(19) United States
(12) Patent Application Publication
(10) Pub. No.: US 2017/0139014 A1
(43) Pub. Date: May 18, 2017

(54) ENERGY STORAGE BATTERY, ENERGY STORAGE-BATTERY MONITORING METHOD AND MONITORING CONTROLLER

(71) Applicant: Kabushiki Kaisha Toshiba, Tokyo (JP)

(72) Inventors: Takahiro YAMAMOTO, Tokyo (JP); Masatake SAKUMA, Tokyo (JP); Takenori KOBAYASHI, Tokyo (JP); Shinichiro KOSUGI, Yokohama (JP); Mami MIZUTANI, Tokyo (JP); Yasuji SAKATA, Tokyo (JP); Toshiro SHIMADA, Tokyo (JP)

(21) Appl. No.: 15/420,774

(22) Filed: Jan. 31, 2017

Related U.S. Application Data
(63) Continuation of application No. PCT/JP2015/055551, filed on Feb. 26, 2015.

(51) Int. Cl. G01R 31/36; H01M 10/42; H02J 7/00; H01M 10/48

(52) U.S. Cl. CPC G01R 31/3658; G01R 31/3606; G01R 31/3679; H01M 10/482; H01M 10/425; H02J 7/0021; H01M 2010/4278; H01M 2010/4271

(57) ABSTRACT

According to one embodiment, an energy storage battery includes: a plurality of cells; an acquirer to acquire measured values of state amounts of the cells; a first parameter calculator to calculate first parameters for evaluating the cells, based on the measured values; and a communicator to transmit the first parameters to a monitoring controller via a communication network.

### CROSS REFERENCE TO RELATED APPLICATIONS

This application is a Continuation of International Application No. PCT/JP2015/55551, filed on Feb. 26, 2015,the entire contents of which is hereby incorporated by reference.

### FIELD

Embodiments described herein relate to an energy storage battery, an energy storage-battery monitoring method, and a monitoring controller.

### BACKGROUND

Stationary large energy storage systems (ESS) can be used for improving power quality, such as, stabilizing power and restriction on frequency variation, in a power system or a local system in, for example, a factory or a building. Moreover, the stationary large energy storage systems have a charge and discharge function of discharging power at the time of peak use by customers, charging remaining power, etc. Such stationary energy storage systems are expected to have market growth.

The stationary large energy storage systems are often connected to an analysis system for analyzing measured data via a communication network. The energy storage systems use a large number of unit batteries (cells) for achieving high performance. For grasping cell states, the analysis system requires a data amount related to cell measurements. However, if there is a large number of cells, a large-capacity communication line is required due to a large amount of measured data on cell states required for communication. Due to such problems of data amount and communication line, it is difficult to grasp the cell states in real time. Therefore, it is general to perform functional maintenance by replacing a battery module including the cells, a batter board, etc. at regular intervals. However, it is desired from now on to continuously use a usable battery module, batter board, etc. with no replacements as much as possible, considering growing environmental awareness.

### BRIEF DESCRIPTION OF THE DRAWINGS

FIG. 1 is a block diagram schematically showing an example of configuration of an energy storage system according to an embodiment of the present invention;

FIG. 2 is a diagram schematically showing an example of configuration of a battery module;

FIG. 3 is a diagram schematically showing an example of configuration of a battery board;

FIG. 4 is a block diagram showing an example of configuration and connection of CMUs and BMUs;

FIG. 5A and FIG. 5B are an illustration showing examples of a QV curve and a dQdV curve;

FIG. 6A is an illustration showing an example of a relationship between the dQdV curve and a feature amount, and FIG. 6B shows examples of feature amounts;

FIG. 7 is an illustration showing an example of a relationship between a feature amount calculated from the dQdV curve and a degraded state;

FIG. 8 schematically shows an example of a flowchart of a process performed by the energy storage system according to the embodiment of the present invention;

FIG. 9 shows an example of a flowchart of a maintenance-parameter calculation process performed by a CMU;

FIG. 10 shows an example of a flowchart of a maintenance-parameter calculation process performed by a BMU; and

FIG. 11 shows an example of a flowchart of a maintenance determination process by a local controller;

### DETAILED DESCRIPTION

According to one embodiment, an energy storage battery includes: a plurality of cells; an acquirer to acquire measured values of state amounts of the cells; a first parameter calculator to calculate first parameters for evaluating the cells, based on the measured values; and a communicator to transmit the first parameters to a monitoring controller via a communication network.

Embodiments will now be explained with reference to the accompanying drawings.

### Embodiment of Present Invention

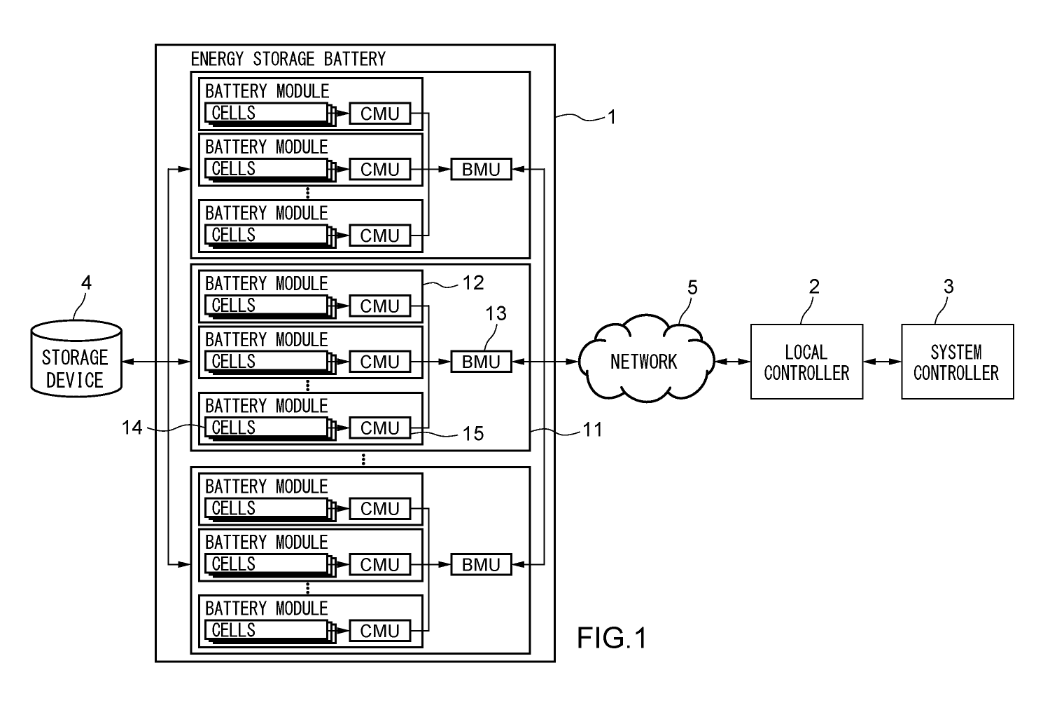

FIG. 1 is a block diagram schematically showing an example of an energy storage system according to an embodiment of the present invention. The energy storage system according to the embodiment of the present invention is provided with an energy storage battery 1 and a storage device 4. The energy storage system is connected to a monitoring controller 7 via a communication network 5. The communication network 5 may be a wired network, a wireless network, or a wired-wireless hybrid network. The monitoring controller 7 includes a local controller 2 and a system controller 3. The local controller 2 is connected to the system controller 3 in wired or wireless connection. The local controller 2 and the system controller 3 may be integrated to one controller.

The energy storage battery 1 has one or more battery boards 11. Each battery board 11 has one or more battery modules 12 and one BMU (Battery Management Unit) 13. Each battery module 12 has a plurality of unit batteries (cells) 14 and one CMU (Cell Monitoring Unit) 15. The number of battery modules 12 of the battery boards 11 may be the same or different from one another. The number of cells 14 of the battery modules 12 may be the same or different from one another. Here, each battery board 11 has one BMU and each battery module 12 has one CMU. However, each battery board 11 and each battery module 12 may have a plurality of BMUs and CMUs, respectively.

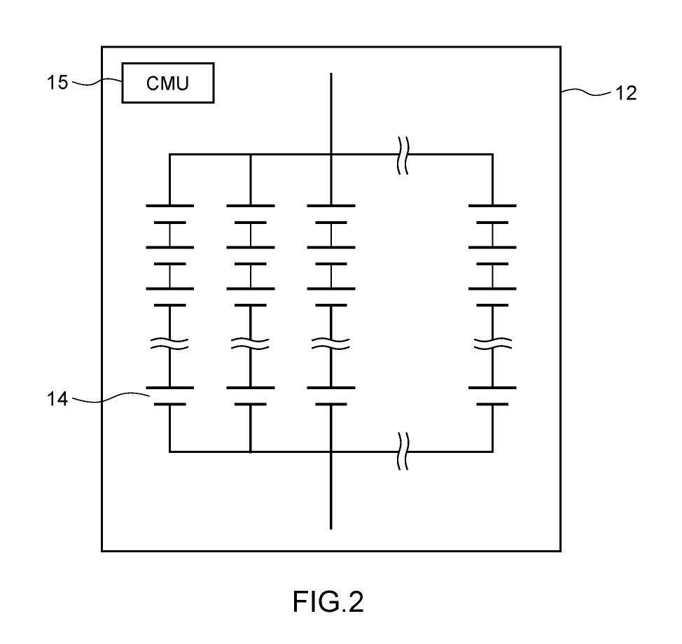

FIG. 2 is a diagram schematically showing an example of configuration of the battery module 12 according the embodiment of the present invention. The battery module 12 has a plurality of cells 14 connected in series and parallel. The configuration shown in FIG. 2 is an example, so that the cells 14 may be connected in series only or parallel only.

The cells 14 are a chargeable and dischargeable secondary battery which may, for example, be a lithium-ion battery, a lithium-ion polymer battery, a lead storage battery, a nickel-cadmium battery, a nickel-hydrogen battery, etc. It is supposed here that a lithium-ion secondary battery is mainly used.

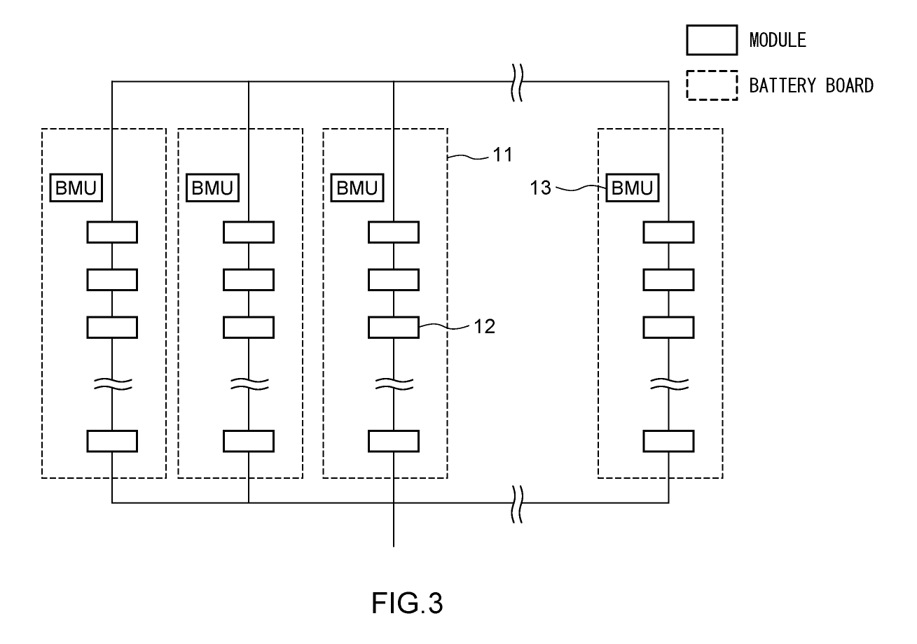

FIG. 3 is a diagram schematically showing an example of configuration of the battery board 11 according the embodiment of the present invention. A plurality of battery boards 11 are connected in parallel. On each battery board 11, a plurality of battery modules 12 are connected in series (in FIG. 1, a plurality of battery modules are connected in parallel to each BMU with an arrow line, which, however, indicates a flow of information, not indicating an actual physical connection relation). The configuration shown in FIG. 3 is an example, so that the battery modules 12 may be connected in parallel or in series and parallel.

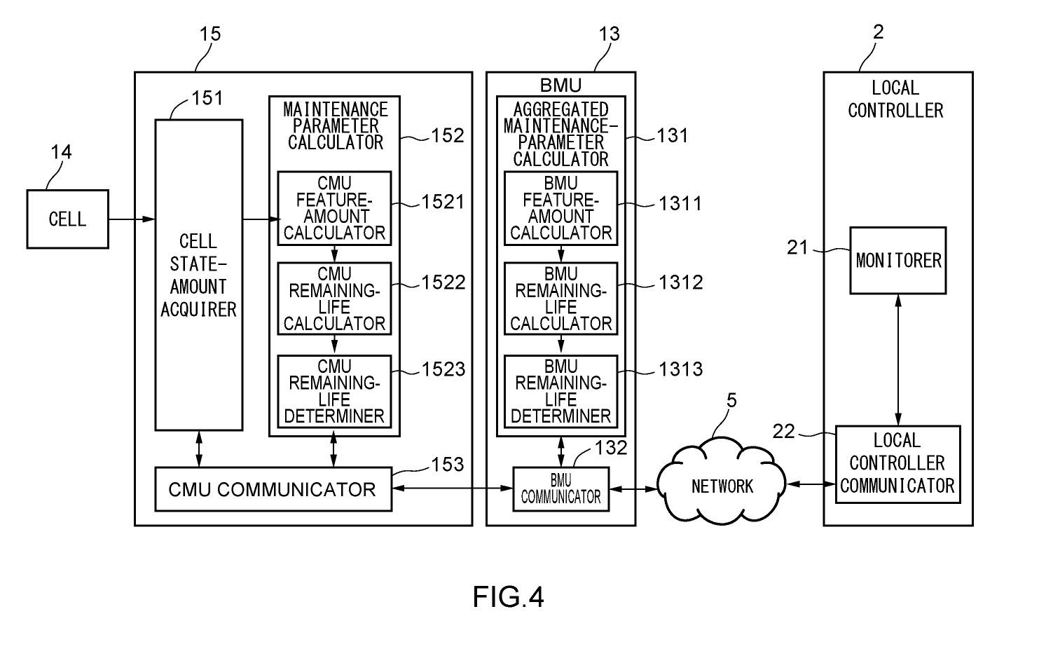

FIG. 4 is a block diagram showing an example of configuration of the CMU 15 and the BMU 13. As shown in FIG. 4, each cell 14 in the battery module 12 is connected to the CMU 15 of the battery module 12. The CMU 15 is connected to the BMU 13 of the battery board 11 having the battery module 12 built therein. The BMU 13 is connected to the local controller 2 of the monitoring controller 7 via the network 5.

The CMU 15 is provided with a cell state-amount acquirer 151, a maintenance parameter calculator 152, and a CMU communicator 153. The maintenance parameter calculator 152 is provided with a CMU feature-amount calculator 1521, a CMU remaining-life calculator 1522, and a CMU remaining-life determiner 1523.

The BMU 13 is provided with an aggregated maintenance-parameter calculator 131 and a BMU communicator 132. The aggregated maintenance-parameter calculator 131 is provided with a BMU feature-amount calculator 1311, a BMU remaining-life calculator 1312, and a BMU remaining-life determiner 1313.

The CMU 15 is a device (monitoring device) for calculating a maintenance parameter related to each cell 14 of the battery module 12 in which the CMU 15 is present. The maintenance parameter is a parameter to be used by the monitoring controller 7 to determine whether maintenance is required for a monitored object (cell, battery module, battery board, etc.). The maintenance includes replacement, inspection, repair, configuration change, etc., however, is not limited thereto. The configuration change is, for example, change in cell connection so as to bypass an abnormal cell.

The cell state-amount acquirer 151 acquires a measured value of information (cell state amount) on the state of each cell 14, from the cell 14 while the energy storage system is running. Each cell has a cell state-amount measuring unit. The cell state-amount acquirer 151 acquires the measured value from the measuring unit. The cell state amount may be any information as long as it is used for inspecting a degraded state of the cell 14, such as, a voltage, current, power, accumulated charge, battery capacity, state of charge (SOC), and surface temperature.

The maintenance parameter calculator 152 calculates a cell maintenance parameter (first parameter) that is a parameter for evaluating a cell based on a measured value of cell state amount acquired by the cell state-amount acquirer 151. The maintenance parameter calculator 152 includes a first parameter calculator for calculating the first parameter. Here, as the cell maintenance parameter, three kinds of parameters are calculated, which are a feature amount, a remaining life, and a result of maintenance determination, which will be described later. The parameter to be calculated may be one kind or a plurality of kinds.

The maintenance parameter calculator 152 may calculate, not only the cell maintenance parameter, but also a battery-module maintenance parameter (second parameter) that is a parameter for evaluating the battery module 12. In this case, the maintenance parameter calculator 152 includes a second parameter calculator for calculating the second parameter. The maintenance parameter calculator 152 calculates a battery-module maintenance parameter based on its own calculated cell maintenance parameters of a plurality of cells. The battery-module maintenance parameter may not be calculated by the maintenance parameter calculator 152, but by the aggregated maintenance-parameter calculator 131 of the BMU 13, which will be described later.

The CMU feature-amount calculator 1521 calculates a cell feature amount. The feature amount is used for determining a cell degraded state, remaining life, etc. The degraded state is a capacity degradation rate or a value of internal resistance, as an example, but not limited thereto. Based on a voltage V and a accumulated charge Q of each cell 14, as measured values of cell state amount, the CMU feature-amount calculator 1521 creates a charge-discharge curve (QV curve) or a differential charge-discharge curve (dQdV curve) of the cell 14 and calculates a feature amount from the created curve.

The QV curve is data (QV data) that indicates the relationship between an accumulated charge Q and a voltage V of an energy storage battery. The dQdV curve is a curve that indicates the relationship between dQ/dV, which is obtained by differentiating a accumulated charge Q of an energy storage battery, with respect to a voltage V, and the voltage V. In other words, the dQdV curve is dQdV data that associates a ratio between the voltage variation of an energy storage battery and the accumulated charge variation of the energy storage battery, with the voltage of the energy storage battery. The QV data and dQdV data are not needed to be expressed in a form of curve but may be expressed in a form of plot set of data points or another form.

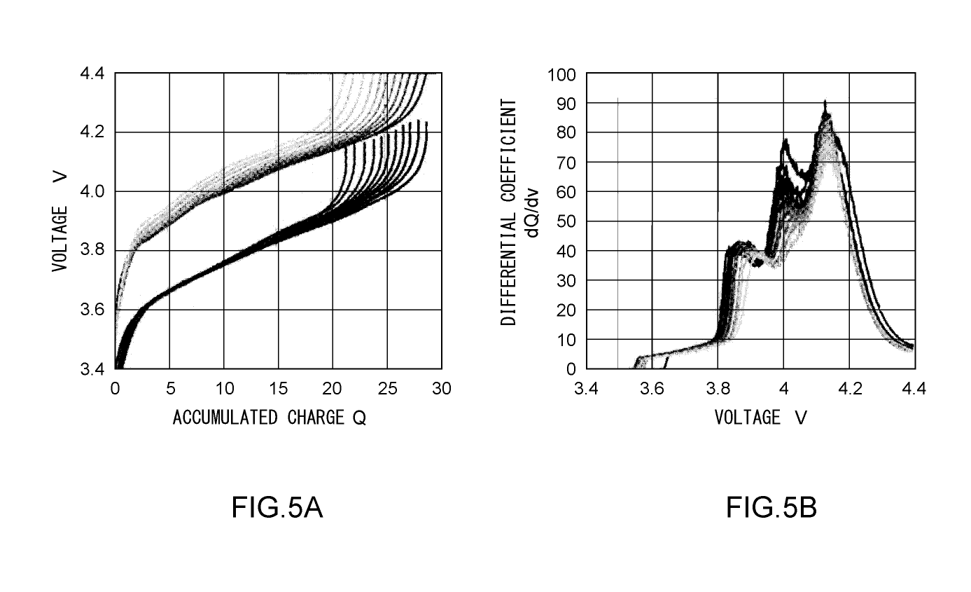

FIG. 5 is an illustration showing examples of the QV curve and dQdV curve. FIG. 5A shows QV curves each per degraded state of an energy storage battery. FIG. 5B shows dQdV curves each generated from each QV curve. As shown in FIG. 5, the shape of QV and dQdV curves varies depending on the degraded state of the energy storage battery. Therefore, from the QV and dQdV curves, a feature amount that correlates with the degraded state of the energy storage battery can be calculated.

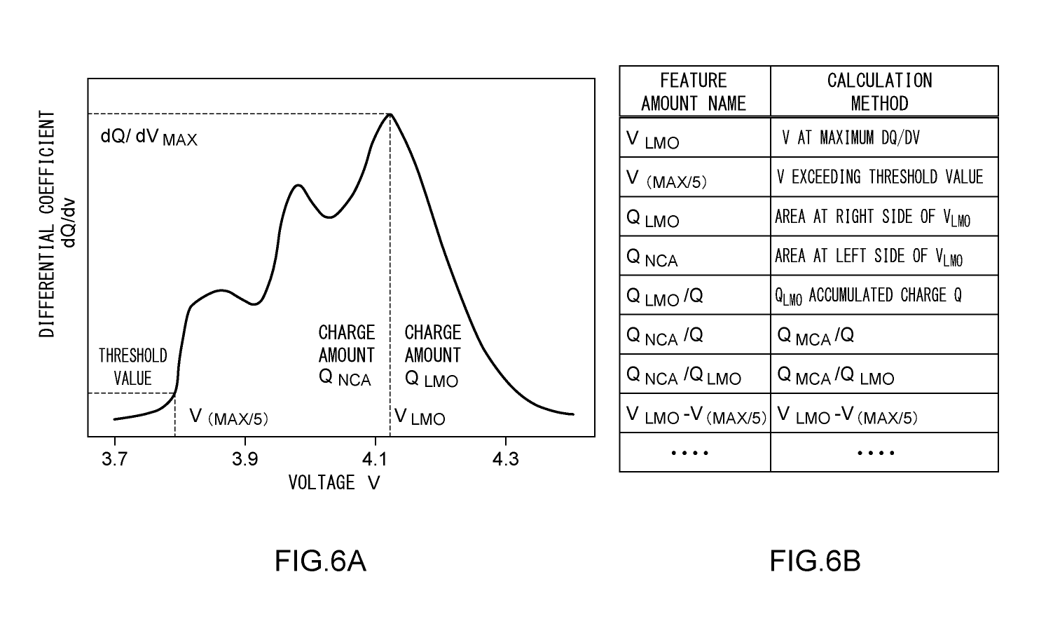

The feature amount is related to the shape of the QV or dQdV curve and calculated using, for example, a minimal value, a maximal value, a peak area, a peak-to-peak distance, a peak height ratio, etc. FIG. 6 is an illustration showing an example of the relationship between the dQdV curve and the feature amount. From the dQdV curve shown in FIG. 6A, feature amounts shown in FIG. 6B can be obtained.

V_{LMO} is a voltage at a maximal value and a maximum value of the dQdV curve. Q_{LMO} is a total accumulated charge that is obtained by integrating the dQdV curve from V_{LMO} to a maximum voltage. In other words, Q_{LMO} is, in FIG. 6A, an area surrounded by a dQdV curve on the right side of a dot line of V_{LMO} and the abscissa. Q_{NCA} is a total accumulated charge that is obtained by integrating the dQdV curve from V_{LMO} to a minimum voltage. In other words, Q_{NCA} is, in FIG. 6A, an area surrounded by a dQdV curve on the left side of the dot line of V_{LMO} and the abscissa. V_{MAX/5} is, when the graph is traced from a lower to a higher voltage, a voltage value at the value of the dQdV curve increased to one fifth of the maximal value and the maximum value of the dQdV curve. Values obtained by subtraction and division of these feature amounts can be used as feature amounts.

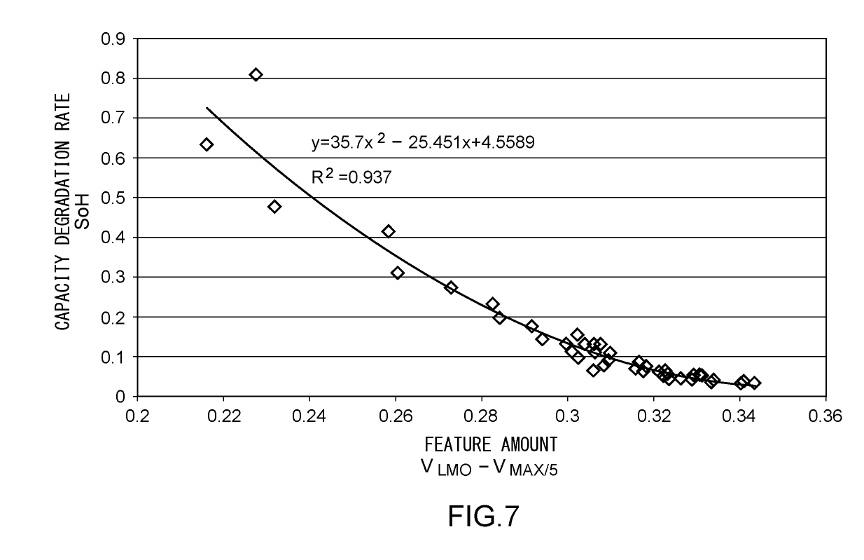

FIG. 7 is an illustration showing an example of the relationship between a feature amount calculated from the dQdV curve and a degraded state. In FIG. 7, the abscissa is V_{LMO}-V_{MAX/5} that is a feature amount and the ordinate is a capacity degraded rate (SoH: State of Health) that indicates a degraded state of an energy storage battery, which gives the current capacity=initial capacity×SOH. As shown in FIG. 7, it is understood that the feature amount V_{LMO}-V_{MAX/5} and the capacity degraded rate correlate with each other.

The CMU feature-amount calculator 1521 may calculate a feature amount of the battery module 12. The feature amount of the battery module 12 is supposed to be the maximum or minimum value of feature amounts of all cells 14 of the battery module 12, an average value of the entire feature amounts, etc. Although the feature amount of the battery module 12 is supposed to be calculated based on the feature amounts of all cells, it may be calculated based on state amounts of some selected cells of the cells. For example, in order to speed up the process, restrict loads, etc., cells 14 for which a result of the previous measurement is good may be eliminated.

The CMU remaining-life calculator 1522 calculates a remaining life from the feature amount calculated by the CMU feature-amount calculator 1521. The remaining life means a remaining term up to the limit at which a monitored object can be safely used. For example, the CMU remaining-life calculator 1522 evaluates the degraded state of the cell 14, a progression rate of the degraded state, etc. based on evaluation data such as the function, in FIG. 7, or a table, which indicates the relationship between the feature amount and the degraded state. Then, the CMU remaining-life calculator 1522 calculates the remaining life based on evaluation data on the relationship between a result of evaluation according to the degraded state of the cells 14 and the remaining life. The evaluation data used for calculating the degraded state, remaining life, etc. may be calculated in advance from past measurement data, data of a previously conducted degradation test, etc. The CMU remaining-life calculator 1522 may be omitted if the remaining life is not included in the maintenance parameter.

When calculating the remaining life of the battery module 12, the CMU remaining-life calculator 1522 may use a calculation method different from a calculation method for calculating the remaining life of the cell 14. For example, not by the calculation based on the feature amount of the battery module 12, the minimum value among the remaining lives of all cells 14 of the battery module 12, the average value of the remaining lives of all cells 14 of the battery module 12, etc. may be calculated as the remaining life of the battery module 12.

The CMU remaining-life determiner 1523 performs cell evaluation based on the remaining life calculated by the CMU remaining-life calculator 1522. As an example of evaluation, it is determined (maintenance determination) whether there is a necessity of maintenance of a monitored object, such as, whether cell maintenance is necessary or not. The maintenance determination may, for example, be performed to determine whether the remaining life is equal to or larger than a threshold value that is a value obtained from past measurement data, obtained by a test, etc. A result of determination may include a numerical value such as a difference between the remaining life and the threshold value. The BMU 13, the local controller 2, etc. may determine the urgency of maintenance or the like based on the numerical value. If the result of determination is not included in the maintenance parameter, the CMU remaining-life determiner 1523 may be omitted.

When calculating the result of maintenance determination on the battery module 12, the CMU remaining-life determiner 1523 may use a calculation method different from a calculation method for calculating the result of maintenance determination on the cell 14. For example, not by the calculation based on the remaining life of the battery module 12, it may be determined that maintenance is not necessary as the result of maintenance determination on the battery module 12, if the result of maintenance determination on all cells 14 of the battery module 12 shows that maintenance is not necessary.

The calculation methods to be performed by, and parameters, threshold values, etc. to be used by the components of the CMU 15 may be stored in the storage device 4 and looked up to when performing the process. Or they may be stored in a storage unit (not shown) in the CMU 15. These calculation methods can be updated by an instruction from the local controller 2, the system controller 3, etc. Moreover, a plurality of methods may be prepared as those calculation methods and used as required by an instruction from the local controller 2 or the like.

The CMU 15 sends the calculated cell maintenance parameter and battery-module maintenance parameter to the BMU 13 via the CMU communicator 153. The BMU 13 as the destination may be determined in advance. Here, it is supposed that those parameters are sent to the BMU 13 on the battery board 11 on which the CMU 15 is present. Moreover, the CMU 15 sends the cell state amount, cell maintenance parameter, and battery-module maintenance parameter to the storage device 4. Here, although there is one CMU communicator 153, a plurality of CMU communicators may be provided per destination.

Since a measured voltage value of the cell state amount includes a component originated from the internal resistance of the cell 14 in an actual situation, the generated QV curve and dQdV curve lack accuracy. Therefore, in order to correctly calculate the feature amount, the CMU feature-amount calculator 1521 may have a function of correcting a measured value of the cell state amount.

As the internal resistance, there are two kinds that are ohmic resistance and non-ohmic resistance. The ohmic resistance correlates with the cell degraded state and the non-ohmic resistance correlates with the cell degraded state and charge-discharge tendency. Therefore, when correcting a measured voltage value, the CMU feature-amount calculator 1521 acquires data on the cell degraded state or data on the charge-discharge tendency.

As the data on the cell degraded state, a result of evaluation of the degraded state of the cell 14 calculated by the CMU remaining-life calculator 1522 can be used. The CMU feature-amount calculator 1521 can calculate the ohmic resistance based on a result of evaluation by the CMU remaining-life calculator 1522 and relation data that indicates the relationship between the degraded state and the ohmic resistance, calculated in advance from past measured data, data of a degradation test previously performed, etc. Then, the calculated ohmic resistance is multiplied by a measured current value included in the cell state amount to obtain a voltage (expressed as V_{CT}) due to the ohmic resistance.

A charge-discharge tendency is bias in charging and discharging operations. While the energy storage system is running, the cell 14 repeats charging and discharging. There is a tendency for charging and discharging to be temporarily inclined to a charging side or a discharging side. This bias is referred to as the charge-discharge tendency. The charge-discharge tendency can be obtained from increase and decrease in accumulated charge Q included in the cell state amount. In feature amount calculation, the CMU feature-amount calculator 1521 determines the charge-discharge tendency. In advance, relation data that indicates the relationship between the charge-discharge tendency and the non-ohmic resistance is calculated from past measured data, data of a degradation test performed in advance, etc. From a result of determination on the charge-discharge tendency, the CMU feature-amount calculator 1521 can calculate non-ohmic resistance based on the relation data. Then, the calculated non-ohmic resistance is multiplied by a current included in the cell state amount to obtain a voltage (expressed as V_{d}) due to the non-ohmic resistance.

Subtraction of V_{CT} and V_{d} from a voltage in the cell state amount gives a voltage having a voltage component due to internal resistance extracted. This voltage may be used instead of the voltage in the cell state amount to perform again the processes that follow the calculation of the feature amount. In performing the above-described correction, the CMU remaining-life calculator 1521 may feed-back a result of evaluation of the degraded state of the cell 14 performed before the calculation of remaining life to the CMU feature-amount calculator 1521. The CMU feature-amount calculator 1521 may correct the QV curve and dQdV curve based on the result of evaluation of the degraded state of the cell 14.

The BMU 13 is a device (monitoring device) for calculating new maintenance parameters based on maintenance parameters calculated by the CMU 15. Based on cell maintenance parameters calculated by the CMU 15, the aggregated maintenance-parameter calculator 131 of the BMU 13 calculates a battery-module maintenance parameter (second parameter), and a battery-board maintenance parameter (third parameter) that is a parameter for evaluating the battery board 11. The aggregated maintenance-parameter calculator 131 includes a second parameter calculator for calculating the second parameter and a third parameter calculator for calculating the third parameter. When the CMU 15 also calculates the battery-module maintenance parameter, the aggregated maintenance-parameter calculator 131 calculates the battery-board maintenance parameter based on either one of or both of the cell maintenance parameter and battery-module maintenance parameter. In this case, the aggregated maintenance-parameter calculator 131 may not include the second parameter calculator. The BMU communicator 132 of the BMU 13 sends the cell maintenance parameter, the battery-module maintenance parameter, and the battery-board maintenance parameter to the local controller 2 and also sends the calculated maintenance parameters to the storage device 4.

The BMU feature-amount calculator 1311 calculates the feature amount of either one of or both of the battery board 11 and the battery module 12. The remaining-life calculator 1312 of the BMU 13 calculates the remaining life of either one of or both of the battery board 11 and the battery module 12. The remaining life determiner 1313 of the BMU 13 calculates the result of maintenance determination of either one of or both of the battery board 11 and the battery module 12. The calculation and determination methods of the components of the BMU 13 may be the same as those used by the CMU 15, the same as that for the cell maintenance parameter, or the same as that for the battery-module maintenance parameter. Moreover, the calculation and determination methods may be different from those mentioned above.

The calculation methods to be performed by, and parameters, threshold values, etc. to be used by the components of the BMU 13 may also be acquired from the storage device 4, when performing the processes, like the CMU 15, or may be prestored in a storage unit (not shown) in the BMU 13. These calculation methods can be updated by an instruction from the local controller 2, the system controller 3, etc. Moreover, a plurality of methods may be prepared as those calculation methods and used as required by an instruction from the local controller 2 or the like.

The local controller 2 is a controller for monitoring and controlling the energy storage system. The local controller 2 identifies a cell that requires maintenance from the acquired cell maintenance parameter. Moreover, the local controller 2 identifies a battery module that requires maintenance from the battery-module maintenance parameter. Furthermore, the local controller 2 identifies a battery board that requires maintenance from the battery-board maintenance parameter. It is supposed that the local controller 2 is installed in, for example, a remote place apart from the battery board 11, and the local controller 2 and the BMU 13 perform data communication via the communication network 5. Nevertheless, the local controller 2 may be directly connected to the battery board 11. Moreover, the local controller 2 may monitor PCS (Power Conditioning System, not shown) that supplies a current to the battery board 11.

There may be a plurality of local controllers 2. For example, the battery boards 11 may be divided into some groups, so that each local controller 2 monitors the battery boards 11 of a group associated with the local controller 2.

A monitorer 21 of the local controller 2 acquires several kinds of maintenance parameters (at least either one of the cell maintenance parameter, battery-module maintenance parameter, and battery-board maintenance parameter) via a local controller communicator 22, and identifies a component that requires maintenance based on the several kinds of maintenance parameters. If a result of maintenance determination is included in the several kinds of maintenance parameters, the result may be used for determination. If the result of maintenance determination is not included in the several kinds of maintenance parameters, based on the feature amount or remaining life, and like the CMU 15 or BMU 13, the calculation of remaining life or maintenance determination is performed and then the component that requires maintenance is determined. When the component that requires maintenance is identified, the part is identified to and maintenance is requested to the system controller 3. As an example, maintenance may be requested if there is at least one result of maintenance determination that shows the necessity of maintenance. Moreover, if the result of maintenance determination includes values each being a difference between the remaining life and threshold value, maintenance determination may be performed taking all of a sum total of, an average of the values, etc. into consideration.

The monitorer 21 performs instructions on, for example, change in calculation method performed by, maintenance parameter used by the BMU 13 or the CMU 15 via the local controller communicator 22. The change may be made by updating information stored in the storage device 4 or directly instructed to the BMU 13 or the CMU 15. The instruction to the CMU 15 may be performed via the BMU 13.

The system controller 3 is a controller for total management of the local controller 2 in a large-scale energy storage system. When a maintenance request is received from the local controller 2, it is determined whether to perform maintenance actually. If it is determined to perform maintenance, a maintenance method may be determined. If the maintenance is, for example, offline inspection which requires a shutdown of the energy storage system, it may be determined whether to shut the function of the energy storage system down. Without the determination by the system controller 3, a result of maintenance determination or the like may be displayed to ask for user instructions. As an example of final determination, it may be determined to replace a battery module or a battery board if it is determined that at least one cell in the battery module has a remaining life smaller than a threshold value to require maintenance. If replacement per cell is possible, it may be determined to replace a cell. If reconfiguration of the cells structure by bypassing a part of cells (for example, one of a plurality of series-connected cells is electrically isolated and cells on both sides are directly connected) is possible, such a determination may be made. Moreover, if it is determined that leaving the current state causes no problem although there is a maintenance request, it may be determined not to perform any maintenance. For example, if leaving the current state causes no problem since a maintenance request is directed to only one cell, it may be determined not to perform any maintenance.

If there is one local controller 2 or the local controller 2 has the function of the system controller 3, the system controller 3 is not required.

The storage device 4 is a device for storing the cell state amount, cell maintenance parameter, battery-module maintenance parameter, battery-board maintenance parameter, etc. In addition, data of a maintenance-parameter calculation method and the like may be stored. Here, although there is one storage device 4, a plurality of storage devices 4 may be provided. Moreover, although the storage device 4 is externally connected to the energy storage battery 1, the storage device 4 may be built in the energy storage battery 1.

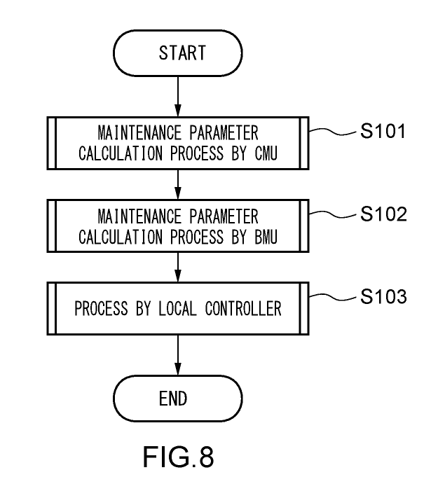

Next, a process to be performed by the energy storage system according to the embodiment of the present invention will be explained. FIG. 8 schematically shows an example of a flowchart of the process performed by the energy storage system according to the embodiment of the present invention.

Each CMU 15 receives an instruction from the local controller 2, BMU 13, etc., or performs a process at a predetermined time or whenever a predetermined period of time passes (S101). Each BMU 13 performs a process based on information calculated by the CMU 15 (S102). The local controller 2 performs a process based on the information calculated by the BMU 13 (S103). Hereinbelow, the processes at the CMU 15, BMU 13, and local controller 2 will be explained.

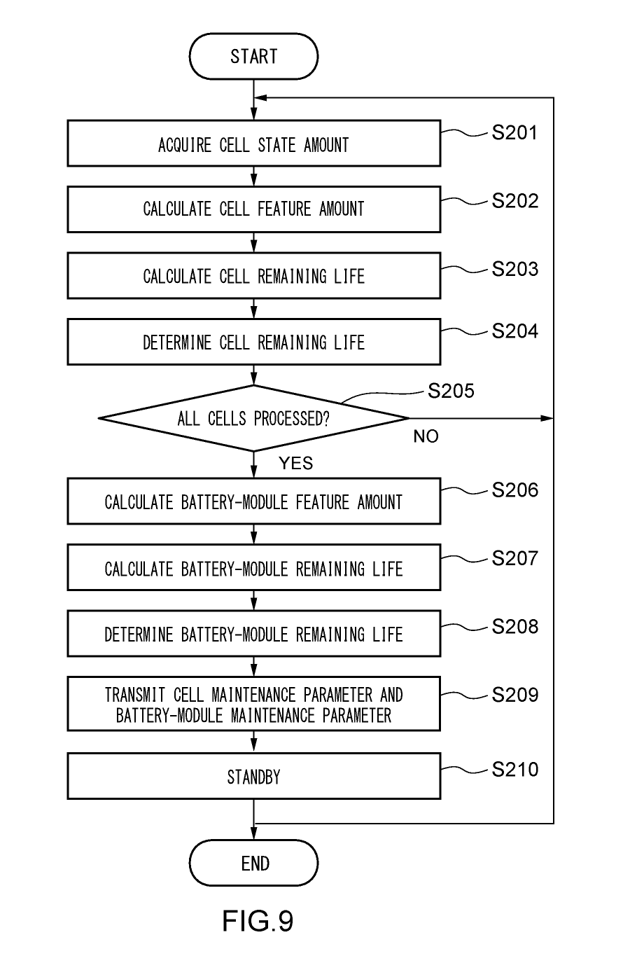

FIG. 9 shows an example of a flowchart of a maintenance-parameter calculation process to be performed by the CMU 15. The cell state-amount acquirer 151 of the CMU 15 acquires a measured value of the cell state amount from a cell 14 located in a battery module 12 having the CMU 15 therein (S201).

The CMU feature-amount calculator 1521 calculates a feature amount of the cell 14 based on the acquired measured value of the cell state amount (S202).

The CMU remaining-life calculator 1522 calculates a remaining life of the cell 14 based on the calculated feature amount of the cell 14 (S203).

The CMU remaining-life determiner 1523 performs maintenance determination on the cell 14 based on the calculated remaining life of the cell 14 (S204).

If the above processes are not performed to all target cells (NO in S205), the CMU 15 performs the above processes to other cells 14 (S201 to S204). If the above processes have been performed to all of the target cells (YES in S205), the CMU feature-amount calculator 1521 calculates a feature amount of the battery module 12 having the CMU 15 based on calculated feature amounts of all cells (S206).

The CMU remaining-life calculator 1522 calculates a remaining life based on the calculated feature amount of the battery module 12 (S207).

The CMU remaining-life determiner 1523 performs maintenance determination on the calculated remaining life of the battery module (S208).

The CMU communicator 153 transmits the calculated battery-module maintenance parameter and cell maintenance parameter to the BMU 13 (S209). The process flow may be changed depending on a result of maintenance determination. For example, if the result of maintenance determination shows the necessity of maintenance for a part of cells, it may be quickly noticed to the local controller 2 and the like. This is the same for the BMU process flow.

The CMU 15 enters a standby mode after transmission (S210), and returns to a process of S201. The standby mode is, as an example, waiting until the passage of a predetermined period of time, until a predetermined time, etc.

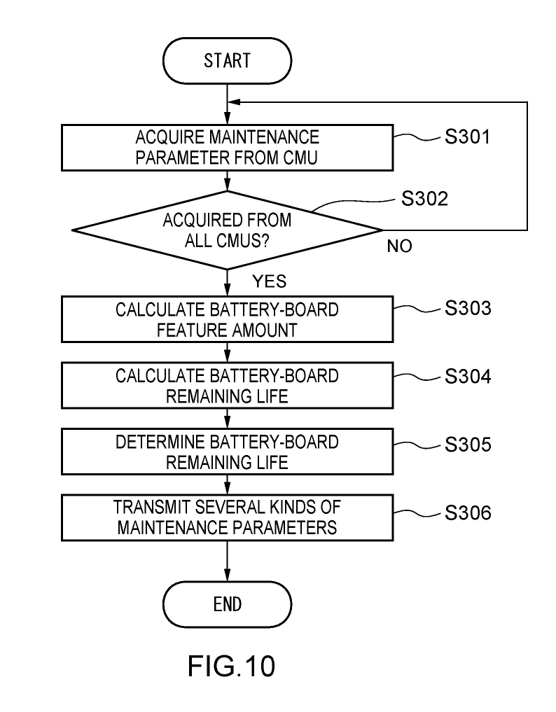

FIG. 10 shows an example of a flowchart of a maintenance-parameter calculation process to be performed by the BMU 13. The BMU communicator 132 acquires the battery-module maintenance parameter and the cell maintenance parameter from the CMU 15 (S301).

If the parameters are not acquired from all target CMUs 15 (NO in S302), the aggregated maintenance-parameter calculator 131 does not do anything, whereas if the parameters have been acquired from all of the target CMUs 15 (YES in S302), the aggregated maintenance-parameter calculator 131 calculates a feature amount of a battery board 11 having the BMU feature-amount calculator 1311 therein (S303).

The remaining-life calculator 1312 calculates a remaining life of the battery board 11 based on the feature amount calculated in step S303 (S304).

The remaining life determiner 1313 performs maintenance determination based on the calculated remaining life (S305).

The BMU communicator 132 transmits the calculated battery-board maintenance parameter and, the cell maintenance parameter and the battery-module maintenance parameter both acquired from the CMU 15 to the local controller 2 (S306).

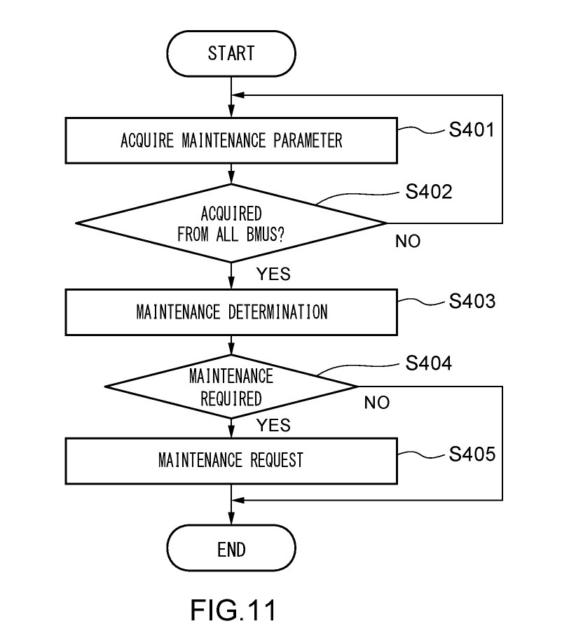

FIG. 11 shows an example of a flowchart of a process by the local controller 2. The local controller communicator 22 acquires several kinds of maintenance parameters from the BMU 13 (S401).

If the parameters are not acquired from all target BMUs 13 (NO in S402), the local controller 2 does not do anything, whereas if the parameters have been acquired from all of the target BMUs 13 (YES in S402), the local controller 2 performs maintenance determination (S403). If a result of maintenance determination is included in the several kinds of maintenance parameters, the result may be used for the determination. If the result of maintenance determination is not included in the several kinds of maintenance parameters, maintenance determination may be performed based on the feature amount or the remaining life.

If it is determined that there is no component that requires maintenance (YES in S404), the process ends. If it is determined that there is a component that requires maintenance (NO in S404), the local controller 2 notices the system controller 3 of a maintenance request for the identified part (S405).

As described above, according to the embodiment of the present invention, measured data of cell state amount is not transmitted from the energy storage system to the local controller, but the maintenance parameters (cell maintenance parameter and the like) calculated at the energy storage system are transmitted. Transmission of measured data of cell state amount requires transmission of measured data at a short sampling interval for, for example, generation of the QV curve, dQdV curve, etc., which results in a large amount of communication depending on the number of cells. On the other hand, according to the present embodiment, since cell maintenance parameters and the like are transmitted, a remote local controller and system controller can monitor and control the energy storage system with no such problems. In other words, while the amount of communication to a remote controller, such as a local controller located on a distant province, is being largely restricted, the cell state and remaining life can be grasped without shutdown of the energy storage system. Therefore, maintenance can be performed before the occurrence of problems while cells are used up to the charge and discharge performance limit. Moreover, since a cell or the like that causes a problem can be identified, maintenance can be performed to a specific part only, which realizes an energy storage system excellent in terms of cost and environment.

Moreover, the CMUs 15, BMUs 13, etc. perform maintenance parameter calculation in parallel, so that a troubled component can be found earlier than by a conventional method of centralized processing.

The processing units of the energy storage battery in the present embodiment may, for example, be realized with a general-purpose computer as basic hardware. In other words, the functions of the processing units of the energy storage battery can be realized by running programs on a processor built in the computer. In this case, the processing units can be realized with programs that are preinstalled in the computer, stored in a storage medium, such as CD-ROM, or distributed via a network and installed in the computer. Moreover, a memory, a hard disk, CD-R, CD-RW, DVD-RAM, DVD-R, etc. built in or externally attached to the computer may be utilized.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A energy storage battery comprising:
a plurality of cells;
an acquirer to acquire measured values of state amounts of the cells;
a first parameter calculator to calculate first parameters for evaluating the cells, based on the measured values; and
a communicator to transmit the first parameters to a monitoring controller via a communication network.

2. The energy storage battery of claim 1, wherein the communicator does not transmit the measured values to the monitoring controller.

3. The energy storage battery of claim 1 further comprising a plurality of battery modules each including the plurality of cells,
wherein each of the battery modules comprises the acquirer and the first parameter calculator.

4. The energy storage battery of claim 1 further comprising:
a second parameter calculator; and
a plurality of battery modules each including the plurality of cells,
wherein the second parameter calculator calculates second parameters for evaluating the battery modules, based on the first parameters, and
the communicator transmits the second parameters to the monitoring controller via the communication network.

5. The energy storage battery of claim 4, wherein each of the battery modules comprises the second parameter calculator.

6. The energy storage battery of claim 4 further comprising at least one battery board including the plurality of battery modules,
wherein the battery board comprises the second parameter calculator.

7. The energy storage battery of claim 4 further comprising:
a third parameter calculator; and
at least one battery board including the plurality of battery modules,
wherein the third parameter calculator calculates a third parameter for evaluating the battery board, based on at least one of the first and second parameters, and
the communicator transmits the third parameter to the monitoring controller via the communication network.

8. The energy storage battery of claim 7, wherein the battery board comprises the third parameter calculator.

9. The energy storage battery of claim 1, wherein the state amounts of the cells each includes at least one of a voltage, currents, a power, an accumulated charge, a battery capacity, or SOC (State Of Charge), of the cell.

10. The energy storage battery of claim 1, wherein the first parameters each include at least one of a feature amount of the cell, a degraded state of the cell, a remaining live of the cell, and performing or not of maintenance of the cell.

11. The energy storage battery of claim 4, wherein the second parameter include at least one of a feature amount of the battery module, a degraded state of the battery module, a remaining live of the battery module, and performing or not of maintenance of the battery module.

12. The energy storage battery of claim 7, wherein the third parameter includes at least one of a feature amount of the battery board, a degraded state of the battery board, a remaining life of the battery board, and performing or not of maintenance of the battery board.

13. The energy storage battery of claim 1, wherein the measured values acquired by the acquirer are stored in an internal or external storage device.

14. The energy storage battery of claim 1, wherein instruction data related to a method of calculating the first parameters is received from the monitoring controller via the network, and
the first parameter calculator calculates the first parameters in accordance with the instruction data.

15. An energy storage-battery monitoring method executed by a computer comprising:
measuring state amounts of a plurality of cells in an energy storage battery;
calculating first parameters for evaluating the cells based on the measured values; and
transmitting the first parameters to a monitoring controller via a communication network.

16. A monitoring controller to communicate with an energy storage battery including a plurality of cells via a communication network, comprising:
a communicator to receive first parameters for evaluating the cells from the energy storage battery, the first parameters being calculated based on measured values of state amounts of the cells; and
a monitorer to monitor the energy storage battery based on the first parameters.
